(19) United States
(12) Patent Application Publication
(10) Pub. No.: US 2025/0309875 A1
(43) Pub. Date: Oct. 2, 2025

(54) POWER-EFFICIENT CLOCK BUFFERS

(71) Applicant: Texas Instruments Incorporated, Dallas, TX (US)

(72) Inventors: Jiahui Tang, Sunnyvale, CA (US); Abishek Manian, San Jose, CA (US); Amit Rane, Santa Clara, CA (US); Sachin Kalia, Richardson, TX (US)

(21) Appl. No.: 18/618,657

(22) Filed: Mar. 27, 2024

(51) Int. Cl. H03K 5/02; H03F 3/45; H03K 5/22

(52) U.S. Cl. CPC H03K 5/023; H03F 3/45165; H03F 3/45174; H03K 5/22

(57) ABSTRACT

Methods, apparatus, and systems are described to facilitate phase detection for data clock synchronization. An example phase detection circuitry includes an oscillator having an output; frequency adjuster circuitry having an input, a first output, and a second output, the input of the frequency adjuster circuitry coupled to the output of the oscillator; a clock buffer circuitry including: a first resistor having a first terminal and a second terminal; and a second resistor having a first terminal and a second terminal, the second terminal of the second resistor coupled to the first terminal of the first resistor; and a feedback amplifier having a first input, a second input, and an output, the first input of the feedback amplifier coupled to a second terminal of the first resistor and a first terminal of the second resistor.

### TECHNICAL FIELD

This description relates generally to circuits, and, more particularly, to power-efficient clock buffers.

### BACKGROUND

Clock generation circuitry generates a clock signal that may be used by one or more components of a system. In some systems (e.g., high-speed clock distribution systems), clock buffers are used as an output stage to generate high-swing clock signal(s) and driver load stage(s) (e.g., output components). The clock buffer drives next stage components with sufficient driving power to avoid distorting the generated clock signal. Also, a clock buffer can take a single input clock signal from the clock generation circuitry and distribute multiple copies of the input clock signal as an output of the clock buffer.

### SUMMARY

For power-efficient clock buffers, an example circuit includes a first transistor having a control terminal, a first current terminal, and a second current terminal. The circuit includes a second transistor having a control terminal, a first current terminal, and a second current terminal. The circuit includes a third transistor having a control terminal, a first current terminal, and a second current terminal, the control terminal of the third transistor coupled to the second current terminal of the second transistor, the first current terminal of the third transistor coupled to the second current terminal of the first transistor. The circuit includes a fourth transistor having a control terminal, a first current terminal, and a second current terminal, the control terminal of the fourth transistor coupled to the second current terminal of the first transistor and the first current terminal of the third transistor, the first current terminal of the fourth transistor coupled to the second current terminal of the second transistor and the control terminal of the third transistor. The circuit includes a first resistor having a first terminal and a second terminal, the first terminal of the first resistor coupled to the second current terminal of the third transistor. The circuit includes a second resistor having a first terminal and a second terminal, the first terminal of the second resistor coupled to the second current terminal of the fourth transistor. Other examples are described.

For power-efficient clock buffers, an example apparatus includes: a first resistor having a first terminal and a second terminal; a second resistor having a first terminal and a second terminal, the second terminal of the second resistor coupled to the first terminal of the first resistor; and a common mode voltage node, the second terminal of the second resistor coupled to the first terminal of the first resistor via the common mode voltage node. The apparatus includes a feedback amplifier including: a third resistor having a first terminal and a second terminal; a current source circuitry having a first terminal and a second terminal, the second terminal of the current source circuitry coupled to the first terminal of the third resistor; and an amplifier having a first input terminal, a second input terminal, and an output terminal, the first input terminal of the amplifier coupled to the second terminal of the first resistor and the first terminal of the second resistor, the second input terminal of the amplifier coupled to the second terminal of the current source circuitry and the first terminal of the third resistor. Other examples are described.

For power-efficient clock buffers, an example apparatus includes an oscillator having an output. The apparatus includes frequency adjuster circuitry having an input, a first output, and a second output, the input of the frequency adjuster circuitry coupled to the output of the oscillator; a clock buffer circuitry including: a first resistor having a first terminal and a second terminal; and a second resistor having a first terminal and a second terminal, the second terminal of the second resistor coupled to the first terminal of the first resistor; and a feedback amplifier having a first input, a second input, and an output, the first input of the feedback amplifier coupled to a second terminal of the first resistor and a first terminal of the second resistor. Other examples are described.

### BRIEF DESCRIPTION OF THE DRAWINGS

FIG. 1 is a block diagram of an example system having computing devices that include a transmitter and a receiver consistent with examples described herein.

FIG. 2 is a block diagram of one example of the receiver of FIG. 1.

FIG. 3 is a block diagram of an example implementation of the clock distribution circuitry of FIG. 2.

FIG. 4 is a block diagram of an alternative example implementation of the clock distribution circuitry of FIG. 2.

FIG. 5A is an example circuitry implementation of a clock buffer of FIGS. 3 and 4.

FIG. 5B is an alternative example circuit implementation of the clock buffer of FIG. 5A.

FIG. 6 is an example circuitry implementation of the clock distribution circuitry of FIG. 3.

FIG. 7 is an example circuitry implementation of the clock distribution circuitry of FIG. 4.

The same reference numbers or other reference designators are used in the drawings to designate the same or similar (functionally or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines or boundaries may be idealized. In reality, the boundaries or lines may be unobservable, blended, irregular, etc.

Clock generation circuitry generates a clock signal that can be used by one or more components of a system. For example, clock generation circuitry may be used to create a clock signal that is used in retimer circuitry in an automotive system. Retimer circuitry includes a receiver, which includes clock and data recovery circuitry, and a transmitter. The receiver receives serial data from one or more computing devices in a system, such as one or more sensors. The receiver may retime the received serial data, convert the serial data to parallel data, and provide the parallel data to a digital processor for processing. After the digital processor processes the parallel data, the digital processor forwards the parallel data to a transmitter.

The transmitter serializes the data from the digital processor and sends out the serialized data to one or more other devices via a network connection. In some examples, receivers may utilize clock and data recovery circuitry to generate a clean recovered clock signal responsive to the input data. The clock may be used by a sampler to sample the input data to reproduce the input data with low jitter. Also, transmitters convert parallel data into serial data that the transmitter transmits via the network connection. The functionality of one or more components of the retimer depends on a clock signal generated by clock signal generation circuitry.

In some examples, clock generation circuitry may include one or more oscillators and a clock buffer. The clock buffer outputs the clock signal generated by the one or more oscillators, but without drawing significant current from the oscillators. For example, if no clock buffer were used, the output clock signal from the one or more oscillators would drive components using generated clock signals. However, because the one or more oscillators do not have enough driving strength to drive the components, the clock signal will be significantly distorted.

Some clock buffers include emitter follower circuitry. However, emitter follower circuitry requires a high bias current to achieve a high slew rate. Accordingly, emitter follower circuitry to implement a clock buffer consumes significant power and lowers the overall clock path power efficiency.

Other clock buffers replace emitter follower circuitry with one or more other clock buffer topology. However, such clock buffers include one or more inductors to extend the operational bandwidth of the clock buffer. Inductors correspond to larger physical layout area and increase routing complexity.

Examples described herein include clock buffer circuitry having an active pull-down path with cross-coupled common emitter pair transistors. Accordingly, the pull-down strength of the described clock buffer circuitry changes with the input signal swing, thereby resulting in increased power efficiency to lower bias currents when possible. Accordingly, examples described herein include clock buffer circuitry that achieves a high slew rate in a power-efficient manner without consuming significant physical layout area to implement.

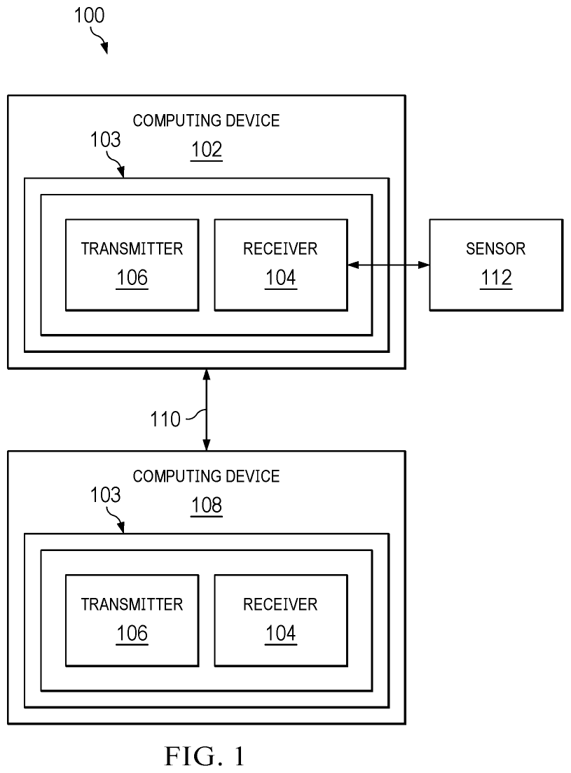

FIG. 1 illustrates an example system 100 including computing devices 102, 108 that communicate with each. The computing devices 102, 108, each include example retimer circuitry 103 including an example receiver 104 and an example transmitter 106. The computing devices 102, 108 communicate with each other via a channel 110. Although the system 100 of the example of FIG. 1 includes two computing devices 102, 108, there may be any number of computing devices connected via the channel 110.

In an example, computing devices 102, 108 of FIG. 1 also include processing devices that implement one or more protocols that enable the corresponding transmitter 106 and receiver 104 to communicate with each other using serial data via the channel 110. The computing devices 102, 108 may be computers, servers, edge or cloud nodes, electrical control units, electronic control modules, or any other processing devices.

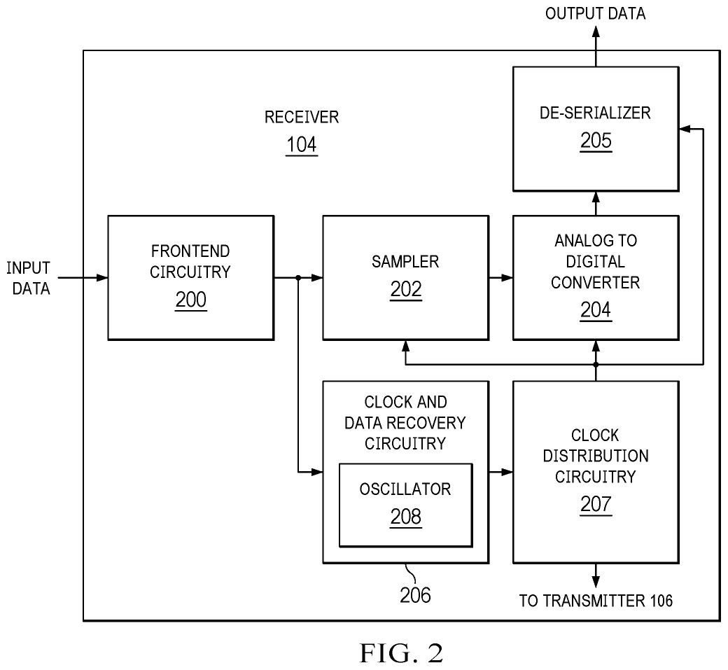

The receiver 104 of the retimer 103 of FIG. 1 receives serial data encoded in analog signals via the channel 110 and converts the encoded analog signals into digital data to be processed by another component (e.g., a digital processor) of the corresponding computing device 102, 108. For example, the receiver 104 uses a clock and recovery protocol to convert data encoded in analog signal(s) to data encoded in digital signal(s). The receiver 104 samples the received analog signal using a clock signal. Also, the receiver 104 determines a phase difference between the clock used to sample the input data/received serial data and the clock used to convert the sampled data into a digital signal. The receiver 104 adjusts the clock signal as part of a clock and data recovery process. The receiver 104 is further described below in conjunction with FIG. 2.

The transmitter 106 of the retimer 103 of FIG. 1 receives parallel data that is to be sent to another computing device and converts the parallel data into a single serial data stream using a clock signal. In some examples, the parallel data is from the receiver 104, after having converted serial data received from another device (e.g., an example sensor 112) into the parallel data. In some examples, the transmitter 106 obtains serial data from the receiver 104 or another device and outputs the parallel data. The transmitter 106 includes serializer circuitry that serializes the parallel data responsive to a clock signal provided by examples described herein. The serial data is latched or gated responsive to a clock signal to so that the data is sampled and forwarded correctly. To avoid adding jitter to the data, the clock signal used by the serializer circuitry is adjusted responsive to a phase difference between the clock signal and the data signal. The adjusting of the clock signal used by the serializer circuitry aligns the clock signal and the data signal at the output of the transmitter 106.

The example channel 110 of FIG. 1 is an interconnection between devices exchanging data. For example, the channel 110 may be a shared interface or media such as a cable, a printed circuit board (PCB) trace, an Ethernet connection, a simultaneous bidirectional link, a point-to-point communication link, a differential connection, a wireless connection, etc. In some examples, the channel 110 represents a physical full-duplex interface that enables transmission and reception on the same connection using a single twisted pair cable. However, the channel 110 may correspond to a different connection, e.g., a different wired or wireless connection.

FIG. 2 is a block diagram of the receiver 104 of FIG. 1. Although FIG. 2 is described in conjunction with the receiver 104 of FIG. 1, FIG. 2 may be described in conjunction with any receiver circuitry. The example receiver 104 of FIG. 2 includes example frontend circuitry 200, example sampler circuitry 202, an example analog-to-digital converter (ADC) 204, example de-serializer circuitry 205, example clock and data recovery circuitry 206, and example clock distribution circuitry 207. In some examples (e.g., for time-interleaved ADCs), the position of the ADC 204 and the de-serialized 205 can be switched.

An input of the frontend circuitry 200 receives input data, e.g. serial data. An output of the frontend circuitry 200 is coupled to an input of the sampler circuitry 202. The sampler circuitry 202 includes two input terminals and an output terminal. The input terminal of the sampler circuitry 202 is coupled to the output terminal of the frontend circuitry 200. The second input terminal of the sampler 202 is coupled to the output terminal of the clock and data recovery circuitry 206. The output terminal of the sampler circuitry 202 is coupled to the analog to digital converter 204. The analog to digital converter 204 includes two input terminals and an output terminal. The first input terminal of the analog to digital converter 204 is coupled to the sampler circuitry 202. The second input terminal of the analog to digital converter 204 is coupled to the clock distribution circuitry 207. The output terminal of the analog digital converter 204 is coupled to the de-serializer circuitry 205. In some examples (e.g., a linear retimer), the ADC 204 may be removed and the sampler 202 may be replaced with sample-and-hold circuitry. In such examples, the output of the sample-and-hold circuitry is coupled to the input of the de-serializer circuitry 205. The de-serializer circuitry 205 includes an input terminal and an output terminal. The input terminal of the de-serializer circuitry 205 is coupled to the output terminal of the analog digital converter 204. The output terminal of the de-serializer circuitry 205 is output to processing circuitry of the computing device and the transmitter of the computer device. The clock and data recovery circuitry 206 includes one input terminal and one output terminal. The input of the clock and data recovery circuitry 206 is coupled to the frontend circuitry 200. The output terminal of the clock and data recovery circuitry 206 is coupled to the clock distribution circuitry 207. The clock distribution circuitry 207 includes an input terminal and three output terminals. The input terminal of the clock distribution circuitry 207 is coupled to the clock and data recovery circuitry 206. The first output terminal of the clock distribution circuitry 207 is coupled to the sampler 202. The second output terminal of the clock distribution circuitry 207 is coupled to the ADC 204. The third output terminal of the clock distribution circuitry 207 is coupled to the transmitter 106 of FIG. 1.

In an example, the frontend circuitry 200 receives data via the channel 110 of FIG. 1. The data may be serial data transmitted from a transmitter implemented in another computing device connected via the channel 110. The frontend circuitry 200 provides the input data to the example sampler 202 and to the clock and data recovery circuitry 206 of FIG. 2.

The sampler circuitry 202 of FIG. 2 samples the serial data from the frontend circuitry 200 responsive to a first clock signal provided by the clock distribution circuitry 207. In some examples, the sampler 202 can be implemented by a latch/flip-flop that receives the serial data and provides the serial data at different points in time responsive to the clock signal. To operate efficiently and without errors, the clock signal used by the sampler circuitry 202 and the clock signal (from the clock distribution circuitry 207) used by the ADC 204 should be aligned. The sampler circuitry 202 provides the sampled data to the input of the ADC 204. The ADC 204 converts the sampled data from the sampler 202 to digital data responsive to a second, adjusted clock signal from the clock distribution circuitry 207. The ADC 204 provides the digital data to the de-serializer circuitry 205. The de-serializer circuitry 205 converts the digital serial data into parallel data. In some examples (e.g., a full-rate retimer), the transmitter circuitry 106 may directly take the serial data from the sampler 202 and transmit the serial data to another device.

In some examples (e.g., a linear retimer), the ADC 204 is not needed. Rather, the sampler 202 can be replaced with sample-and-hold circuitry and the output of the sample-and-hold circuitry is provided to the de-serializer 205. In such examples, the sample-and-hold samples and latches the input data and provides the latched data to the de-serializer 205, which outputs the output data. In some examples (e.g., a full-rate retimer without ADC), the ADC 204 is not needed. Rather, the output of the sampler 202 is coupled to the de-serializer 205, which outputs the output data. In some examples (e.g., a high-speed ADC front-end), the sampler 202 is a sample-and-hold circuit. In such examples, the output of the sample-and-hold circuit is coupled to the de-serializer 205, which outputs the output data. In some examples (e.g., a timer-interleaved ADC), the sampler 202 is a sample-and-hold circuit. In such examples, the output of the sample-and-hold circuit is coupled to the de-serializer 205 and the output of the de-sterilizer 205 is coupled to the ADC 204, which outputs the output data. In some examples (e.g., a full-rate retimer with no ADC or de-serializer 205), the ADC 204 and the de-serializer 205 are not needed. In such examples, the sampler 202 is implemented by a sample and hold circuit, which outputs the output data. FIG. 2 may be replaced with any of these example implementations and/or any other implementation of a retimer circuit.

The example clock and data recovery circuitry 206 of FIG. 2 generates clean clock signals (e.g., a plurality of clock signals with the same frequency) responsive to obtaining the data signal from the frontend circuitry 200. For example, the clock and data recovery circuitry 204 recovers a clean clock signal by slicing the data from the frontend circuitry 200 and comparing data edges with clock edges. The clock and data recovery circuitry 206 may generate the clock signals using an example oscillator 208 (e.g., a local voltage-controlled oscillator (VCO)) and dividers. The output of the oscillator 208 may be coupled to the clock distribution circuitry 207 to provide a clock signal. Also, the clock and data recovery circuitry 206 provides the generated clock signal to the transmitter 106 through the clock distribution circuitry 207. The transmitter 106 uses the generated clock signal to serialize and latch data as part of the transmission process, as further described above. The clock and data recovery circuitry 206 outputs the generated clock signals to the clock distribution circuitry 207 of FIG. 2.

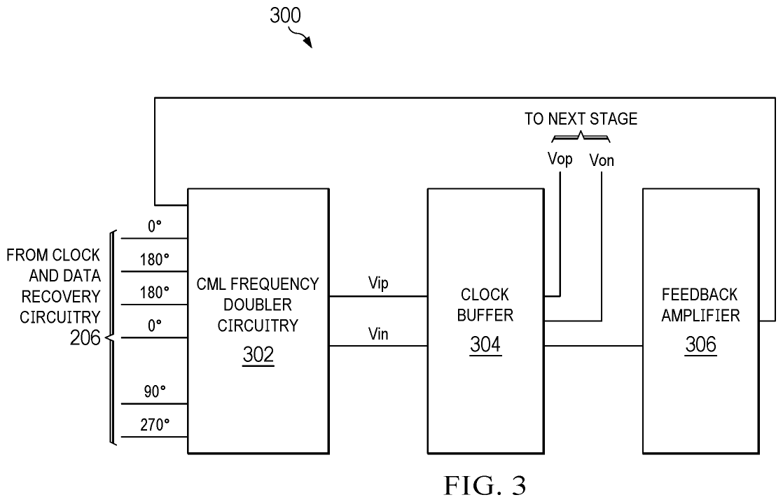

The example clock distribution circuitry 207 of FIG. 2 includes a clock buffer to output clock signals that correspond to the output clock signals of the clock and data recovery circuitry 206 to drive the sampler 202 or the ADC 204. In some examples, if the clock and data recovery circuitry 206 generates a non-full rate clock (e.g., a half-rate clock, a quarter-rate clock, etc.), the clock distribution circuitry 207 includes a frequency adjuster. Also, the clock distribution circuitry 207 may include a feedback amplifier to determine and adjust a common mode voltage of the clock distribution circuitry 207. The clock distribution circuitry 207 is further described below in conjunction with FIGS. 3-7.

FIG. 3 is a block diagram of an example clock distribution circuitry 300. The clock distribution circuitry 300 may be used to implement the clock distribution circuitry 207 of FIG. 2. However, the clock distribution circuitry 300 can be implemented in any device or system that utilizes a clock signal. The clock distribution circuitry 300 includes example current mode logic (CML) frequency doubler circuitry 302, an example clock buffer 304, and an example feedback amplifier 306.

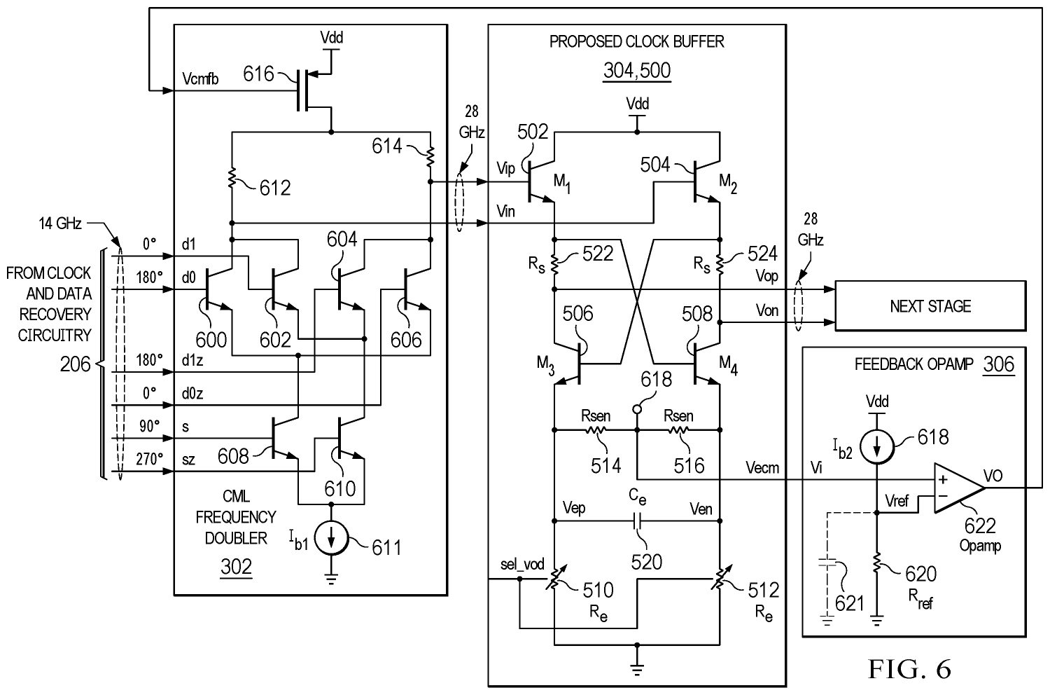

The CML frequency doubler circuitry 302 of FIG. 3 (also referred to as a CML frequency adjuster circuitry) is coupled to the clock and data recovery circuitry 206, the clock buffer 304, and the feedback amplifier 306. However, the CML frequency doubler circuitry 302 can be coupled to any component that generates clock signals. As described above, the clock and data recovery circuitry 206 can generate full-rate clock signals or clock signals that are less than a full clock (e.g., half-clock signals). The CML frequency doubler circuitry 302 obtains one or more clock signals from the clock and data recovery circuitry 206 and generates a first clock signal and a second differential clock signal (e.g., 180 degrees out of phase to the first clock signal/an inverse of the first clock signal) that is double the frequency of the one or more clock signals from the clock and data recovery circuitry 206. For example, if the clock signals from the clock and data recovery circuitry 206 correspond to a 4 GHz frequency, the CML frequency doubler circuitry 302 will generate a first clock signal and a second differential clock signal with an 8 GHz frequency. Using a half-rate clock and a frequency doubler to generate a clock signal may require less resources (e.g., power resource) than implementing a full-rate clock at the clock and data recovery circuitry 206. In some examples, the clock and data recovery circuitry 206 could generate a quarter-rate clock or any other portion of a full rate clock. The CML frequency doubler circuitry 302 outputs the first clock signal to the clock buffer 304 via the voltage input positive (Vip) terminal. Also, the CML frequency doubler circuitry 302 outputs the second differential clock signal to the clock buffer 304 via the voltage input negative (Vin) terminal. Also, the CML frequency doubler circuitry 302 may adjust the characteristics (e.g., amplitude, common mode voltage, etc.) based on an output of the feedback amplifier 306. As further described below, the output of the feedback amplifier 306 corresponds to how much the common mode voltage of the clock buffer 304 deviates from the desired common mode voltage. Accordingly, the CML frequency doubler circuitry 302 can adjust the output clock signals to mitigate the common mode voltage deviation from the clock buffer 304. The CML frequency doubler circuitry 302 could adjust the frequency of the clock signal based on any amount. For example, if the clock and data recovery circuitry 206 is instead implemented by a quarter-rate clock, the CML frequency doubler circuitry 302 can be replaced with frequency multiplier circuitry to output full rate clock signals by multiplying the quarter-rate clock by four. A circuit implementation of the CML frequency doubler circuitry 302 of FIG. 3 is further described below in conjunction with FIG. 6.

The clock buffer 304 of FIG. 3 is coupled to the CML frequency doubler circuitry 302, the feedback amplifier 306, and a next stage component. The next stage could be the sampler 202, the ADC 204, a sample-and-hold circuitry (e.g., to converter into discrete time), a flip flop, or any other circuitry that uses, forwards, or manipulates a clock signal. The clock buffer 304 obtains differential clock signals from the CML frequency doubler circuitry 302 via the Vip terminal and the Vin terminal. The clock buffer 304 outputs the differential clock signals, via the voltage output positive (Vop) and voltage output negative (Von) terminals, to the next stage without risk of drawing significant current from one or more of the clock and data recovery circuitry 206 of the CML frequency doubler circuitry 302. Also, the clock buffer 304 includes a node that corresponds to the common mode voltage of the clock buffer. A common mode voltage is a voltage that is common to both of the differential clock signals at the Vip and Vin terminals with respect to ground. The common mode voltage is provided to the feedback amplifier 306 to adjust the common mode voltage if the common mode voltage deviates from a desired common mode voltage, as further described below. As described above, the clock buffer 304 of FIG. 3 is implemented to conserve area and power. An example circuit implementation of the clock buffer 304 of FIG. 3 is further described below in conjunction with FIG. 6.

The feedback amplifier 306 of FIG. 3 is coupled to the clock buffer 304 and the CML frequency doubler 302. The feedback amplifier 306 obtains the common mode voltage of the clock buffer and compares the common mode voltage to a threshold voltage associated with a desired common mode voltage. The feedback amplifier 306 outputs a voltage based on the difference between the common mode voltage and the threshold voltage. For example, if there is no difference between the common mode voltage and the threshold voltage, the feedback amplifier 306 outputs a particular voltage, which does not affect the clock signals output by the CML frequency doubler circuitry 302. Accordingly, the CML frequency doubler circuitry 302 outputs clock signals that do not change the common mode voltage of the clock buffer 304. However, if there is a difference between the common mode voltage and the threshold voltage, the feedback amplifier outputs a voltage based on the difference. The voltage is provided to the CML frequency doubler circuitry 302 which, in turns, adjusts the clock signals output by the CML frequency doubler circuitry 302. The adjusted clock signal is then fed into the clock buffer 304 to adjust the common mode voltage of the clock buffer 304 to reduce the difference between the common mode voltage at the desired common mode voltage. A circuit implementation of the feedback amplifier 306 of FIG. 3 is further described below in conjunction with FIG. 6.

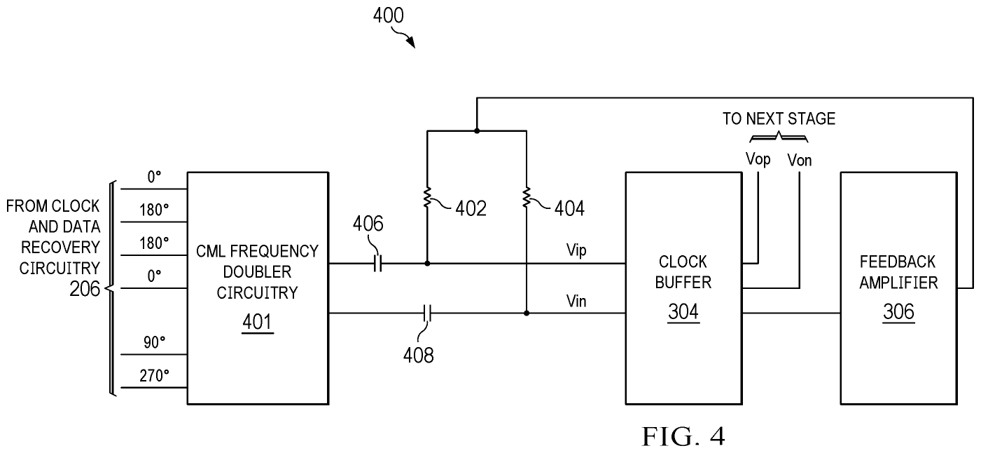

FIG. 4 is a block diagram of an example clock distribution circuitry 400. The clock distribution circuitry 400 may be used to implement the clock distribution circuitry 207 of FIG. 2. However, the clock distribution circuitry 400 can be implemented in any device or system that utilizes a clock signal. The clock distribution circuitry 400 includes the clock buffer 304, and the feedback amplifier 306 of FIG. 3. FIG. 4 further includes the CML doubler circuitry 401, example resistors 402, 404, and example capacitors 406, 408. The structure and function of the clock buffer 304, and the feedback amplifier 306 of FIG. 4 are the same, or substantially similar to the clock buffer 304, and the feedback amplifier 306 of FIG. 3, but for how the components are connected. Accordingly, the clock buffer 304, and the feedback amplifier 306 of FIG. 4 will not further be described except for the differences to FIG. 3. Further description of the clock buffer 304, and the feedback amplifier 306 of FIG. 4 can be ascertained from the description of FIG. 3.

The CML frequency doubler circuitry 401 of FIG. 4 is coupled to the clock and data recovery circuitry 206 of FIG. 2. Also, the CML frequency doubler circuitry 401 is capacitively coupled to the clock buffer 304 and the feedback amplifier 306. The CML frequency doubler circuitry 401 operates in a similar fashion to the CML frequency doubler circuitry 302. However, the output of the feedback amplifier 306 is not used to control the characteristics of the clock signals output by the CML frequency doubler circuitry 401. Accordingly, the CML frequency doubler circuitry 401 does not adjust the clock signals to adjust the common mode voltage of the clock buffer 304. Rather, as further described below, the feedback amplifier 306 outputs a signal to the input terminals of the clock buffer 304 to adjust the common mode voltage of the clock buffer 304.

The resistors 402, 404 of FIG. 4 each include two terminals. The first terminal of the resistor 402 is coupled to the output terminal of the feedback amplifier 306 and the first terminal of the resistor 404. The second terminal of the resistor 402 is coupled to the second terminal of the capacitor 406 and the first input terminal (Vip) of the clock buffer 304. The first terminal of the resistor 404 is coupled to the output terminal of the feedback amplifier 306 and the first terminal of the resistor 402. The second terminal of the resistor 404 is coupled to the second terminal of the capacitor 408 and the second input terminal (Vin) of the clock buffer 304. The resistors 402, 404 are bias resistors that set the input common mode voltage for the clock buffer 304. The input common mode voltage adjusts the clock signals on the Vip and Vin terminals to adjust the common mode voltage of the clock buffer 304.

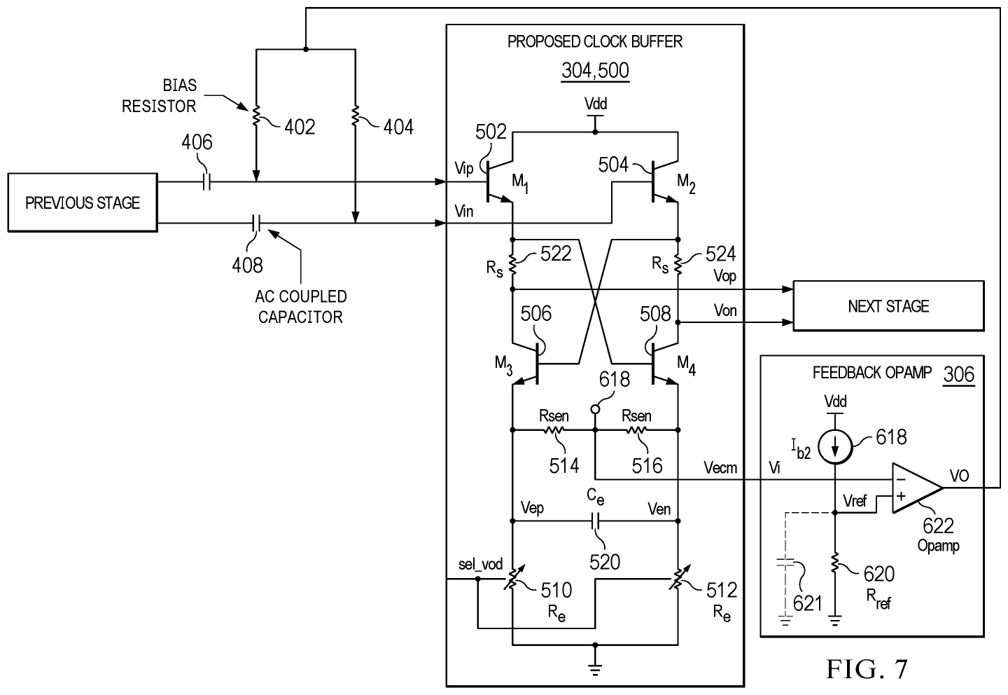

The capacitors 406, 408 of FIG. 4 each include two terminals. The first terminal of the capacitor 406 is coupled to the output terminal of the CML frequency doubler circuitry 401. The second terminal of the capacitor 406 is coupled to the second terminal of the resistor 402 and the input terminal of the clock buffer 304 via the Vip terminal. The first terminal of the capacitor 408 is coupled to the output terminal of the CML frequency doubler circuitry 401. The second terminal of the capacitor 408 is coupled to the second terminal of the resistor 404 and the input terminal of the clock buffer 304 via the Vin terminal. The capacitors 406, 408 are AC coupling capacitors that allow the output signals from the CML frequency doubler circuitry 401 to the clock buffer 304 but blocks the DC output voltage of the feedback amplifier 306 from entering into the CML frequency doubler circuitry 401. A circuit implementation of the clock buffer 304 and the feedback amplifier 306 is further described below in conjunction with FIG. 7.

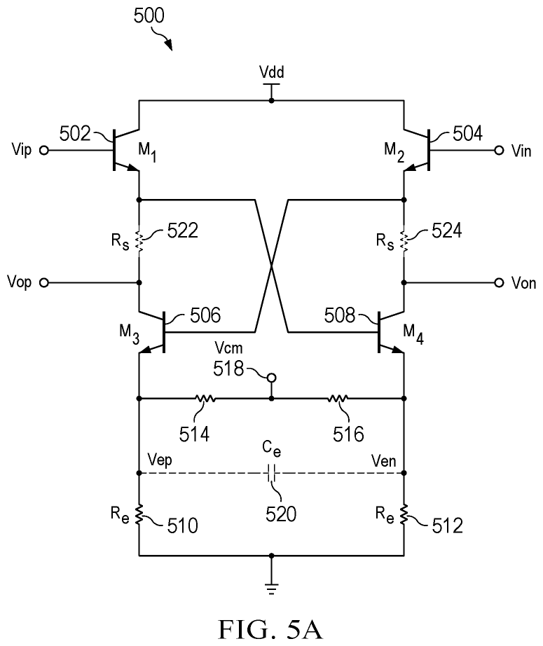

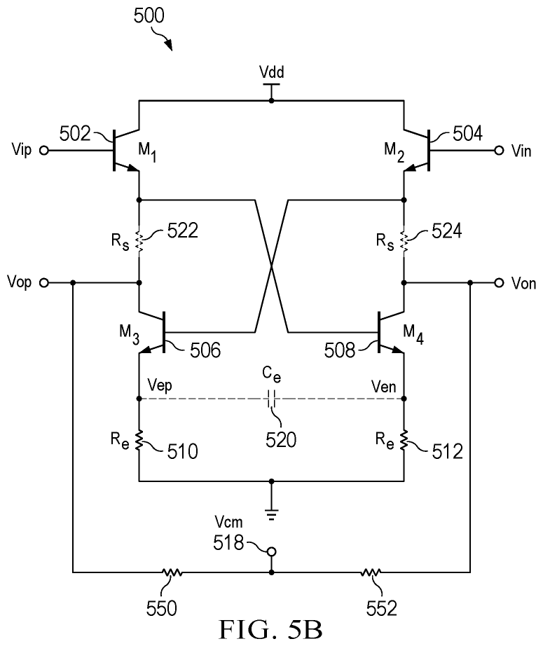

FIG. 5A is an example clock buffer 500. The clock buffer 500 is circuit implementation of the clock buffer 304 of FIGS. 3 and 4. The clock buffer 500 of FIG. 5A includes example transistors 502, 504, 506, 508 and example resistors 510, 512, 514, 516, and an example common mode voltage node 518. In some examples, the clock buffer 500 includes one or more of the example capacitor 520 or the example resistors 522, 524.

The transistors 502, 504, 506, 508 of FIG. 5A are NPN bipolar junction transistors (BJTs). However, the transistors 502, 504, 506, 508 could be any type of transistor. The transistors 502, 504, 506, 508 each include a control terminal (e.g., a base terminal), a first current terminal (e.g., a collector terminal), a second current terminal (e.g., an emitter terminal). The control terminal of the transistor 502 is coupled to the output of the CML frequency doubler circuitry 302, 401 of FIG. 3 or 4 via the Vip terminal. In some examples, the control terminal of the transistor 502 is coupled to the second terminal of the capacitor 406 and the second terminal of the resistor 402. The first current terminal of the transistor 502 is coupled to a supply terminal (e.g., Vdd). The second current terminal of the transistor 502 is coupled to the control terminal of the transistor 508. In some examples, the second current terminal of the transistor 502 is coupled to the first current terminal of the transistor 506 and a next stage component via the Vop terminal. In some examples, the second current terminal of the transistor 502 is coupled to the first terminal of the resistor 522. The control terminal of the transistor 504 is coupled to the output of the CML frequency doubler circuitry 302, 401 of FIG. 3 or 4 via the Vin terminal. In some examples, the control terminal of the transistor 504 is coupled to the second terminal of the capacitor 408 and the second terminal of the resistor 404. The first current terminal of the transistor 504 is coupled to the supply terminal (e.g., Vdd). The second current terminal of the transistor 504 is coupled to the control terminal of the transistor 506. In some examples, the second current terminal of the transistor 504 is coupled to the first current terminal of the transistor 508 and a next stage component via the Von terminal. In some examples, the second current terminal of the transistor 504 is coupled to the first terminal of the resistor 524. The control terminal of the transistor 506 is coupled to the second current terminal of the transistor 504. In some examples, the control terminal of the transistor 506 is coupled to the first terminal of the resistor 524. In some examples, the control terminal of the transistor 506 is coupled to the next stage component and the first current terminal of the transistor 508 via the Von terminal. The first current terminal of the transistor 506 is coupled to the next stage component via the Vop terminal. In some examples, the first current terminal of the transistor 506 is coupled to the second current terminal of the transistor 502 and the control terminal of the transistor 508. In some examples, the first current terminal of the transistor 506 is coupled to the second terminal of the resistor 522. The second current terminal of the transistor 506 is coupled to the first terminal of the resistor 510 and the first terminal of the resistor 514. In some examples, the second current terminal of the transistor 506 is coupled to the first terminal of the capacitor 520. The control terminal of the transistor 508 is coupled to the second current terminal of the transistor 502. In some examples, the control terminal of the transistor 508 is coupled to the first terminal of the resistor 522. In some examples, the control terminal of the transistor 506 is coupled to the next stage component and the first current terminal of the transistor 506 via the Vop terminal. The first current terminal of the transistor 508 is coupled to the next stage component via the Von terminal. In some examples, the first current terminal of the transistor 508 is coupled to the second current terminal of the transistor 504 and the control terminal of the transistor 506. In some examples, the first current terminal of the transistor 508 is coupled to the second terminal of the resistor 524. The second current terminal of the transistor 508 is coupled to the first terminal of the resistor 512 and the second terminal of the resistor 516. In some examples, the second current terminal of the transistor 508 is coupled to the second terminal of the capacitor 520. The transistors 502, 504 operate as common-collector pull-up transistors and the transistors 506, 508 operate as degenerated common-emitter pull-down transistors. The transistors 506, 508 balance the pull-up and pull-down strength of the clock buffer 500.

The resistors 510, 512 of FIG. 5A each include two terminals. The first terminal of the resistor 510 is coupled to the second current terminal of the transistor 506 and the first terminal of the resistor 514. In some examples, the first terminal of the resistor 510 is coupled to the first terminal of the capacitor 520. The second terminal of the resistor 510 is coupled to a common terminal (e.g., the ground terminal). The first terminal of the resistor 512 is coupled to the second current terminal of the transistor 508 and the second terminal of the resistor 516. In some examples, the first terminal of the resistor 512 is coupled to the second terminal of the capacitor 520. The second terminal of the resistor 512 is coupled to the common terminal. The resistors 510, 512 generate a node voltage at the Vep and Ven nodes of the clock buffer 500. The node voltage can be used to generate the common mode voltage at the common mode node 518, as further described below. In some examples, the resistors 510, 512 are variable resistors. In such examples, a processing device (e.g., one or more components of the computing device 102, 108) can select the amount of the resistance of the resistors 510, 512 to change the bias current of the clock buffer 500 to increase or decrease the output swing of the different output clock signals. For example, the processing device can send a signal (e.g., via the sel-vod terminal of FIGS. 6 and 7) to change the resistance of the resistor(s) 510, 512.

The example resistors 514, 516 of FIG. 5A each include a first terminal and a second terminal. The first terminal of the resistor 514 is coupled to the second current terminal of the transistor 506 and the first terminal of the resistor 510. In some examples, the first terminal of the resistor 514 is coupled to the first terminal of the capacitor 520. The second terminal of the resistor 514 is coupled to the first terminal of the resistor 516 and the feedback amplifier 306 of FIG. 3 or 4 via the common mode voltage (Vcm) node 518. The first terminal of the resistor 516 is coupled to the second terminal of the resistor 514 and the feedback amplifier 306 of FIG. 3 or 4 via the common mode voltage (Vcm) node 518. The second terminal of the resistor 516 is coupled to the second current terminal of the transistor 508 and the first terminal of the resistor 512. In some examples, the second terminal of the resistor 514 is coupled to the second terminal of the capacitor 520. The resistors 514, 516 couple the output voltage path and the input voltage path to the Vcm node 518. The voltage at the Vcm node 518 represents the common mode voltage of the clock buffer 500. As further described above, the feedback amplifier 306 of FIG. 3 or 4 compares the voltage at the Vcm node 518 to a desired common mode voltage to determine how much to adjust the common mode voltage.

FIG. 5B illustrates an alternative implementation of the resistors 514, 516 of FIG. 5A. In FIG. 5B, the resistors 514, 516 are replaced with example resistors 550, 552. The resistors 550, 552 each include a first terminal and a second terminal. The first terminal of the resistor 550 is coupled to one or more of the first current terminal of the transistor 506, second terminal of the resistor 522 (e.g., if implemented), the next stage, or the second current terminal of the transistor 502 and the control terminal of the transistor 508 (e.g. if the resistor 522 is not implemented) via the Vop terminal. The second terminal of the resistor 550 is coupled to the first terminal of the resistor 522 via the Vcm node 518. The first terminal of the resistor 552 is coupled to the first terminal of the resistor 550 via the Vcm node 518. The second terminal of the resistor 552 is coupled to one or more of the first current terminal of the transistor 508, second terminal of the resistor 524 (e.g., if implemented), the next stage, or the second current terminal of the transistor 504 and the control terminal of the transistor 506 (e.g. if the resistor 524 is not implemented) via the Von terminal. As in FIG. 5A, the voltage at the Vcm node 518 of FIG. 5B represents the common mode voltage of the clock buffer 500. As further described above, the feedback amplifier 306 of FIG. 3 or 4 compares the voltage at the Vcm node 518 to a desired common mode voltage to determine how much to adjust the common mode voltage.

Returning to FIG. 5A, the capacitor 520 of FIG. 5A is an optional component that includes a first terminal and a second terminal. The first terminal of the capacitor 520 is coupled to the second current terminal of the transistor 506, the first terminal of the resistor 510, and the first terminal of the resistor 514. The second terminal of the capacitor 520 is coupled to the second current terminal of the transistor 508, the second terminal of the resistor 512, and the second terminal of the resistor 516. The capacitor 520 extends the bandwidth of the clock buffer 500. The larger the capacitance of the capacitor 520, the more the bandwidth is extended. However, the larger the capacitance of the capacitor 520, the higher the chance of peaking at the frequency response and the higher the instability of the clock buffer 500. Accordingly, if extended bandwidth is desired, the capacitor 520 can be included in the clock buffer 500 and the amount of capacitance of the capacitor 520 can be selected to balance bandwidth, performance, and stability.

The resistors 522, 524 of FIG. 5A are optional components that each include a first terminal and a second terminal. The first terminal of the resistor 522 is coupled to the second current terminal of the transistor 502 and the control terminal of the transistor 508. The second terminal of the resistor 522 is coupled to the next stage component and the first current terminal of the transistor 506 via the Vop terminal. The first terminal of the resistor 524 is coupled to the second current terminal of the transistor 504 and the control terminal of the transistor 506. The second terminal of the resistor 524 is coupled to the next stage component and the first current terminal of the transistor 508 via the Von terminal. If the resistors 522, 524 are not included in the clock buffer, the resistors 522, 524 are replaced with a short circuit. For example, the second current terminal of the transistor 502 would be coupled to the control terminal of the transistor 508, the second current terminal of the transistor 506, and the next stage component via the Vop terminal and the second current terminal of the transistor 504 would be coupled to the control terminal of the transistor 506, the second current terminal of the transistor 508, and the next stage component via the Von terminal. The resistors 522, 524 can be implemented to increase DC gain and improve stability of the clock buffer 500.

In operation, if the voltage at the Vip terminal is rising and the voltage at the Vin terminal is falling, the voltage at the second current terminal of the transistor 502 will rise to pull up the control terminal of the transistor 508 so that the transistor 508 conducts more current. Also, as the voltage at the Vin terminal is falling, the transistor 504 conducts less current, which stops injecting current into the Von terminal. If the transistor 508 is conducting (e.g., sinking) more than the transistor 504 injects into the Von terminal, the voltage at the Von terminal is pulled down toward ground. Also, because the transistor 504 is not injecting current, the transistor 506 will conduct less current, which prevents the voltage at the Vop terminal from being pulled toward ground. Rather, the current from the second current terminal of the transistor 502 will cause the voltage at the Vop terminal to rise.

If the voltage at the Vip terminal is falling and the voltage at the Vin terminal is raising, the voltage at the second current terminal of the transistor 502 will fall to pull down the control terminal of the transistor 508 so that the transistor 508 conducts less current. Also, as the voltage at the Vin terminal is rising, the transistor 504 will conduce more current, which injects current into the Von terminal. If the transistor 508 is conducting less current than the transistor 504 injects into the Von terminal, the voltage at the Von terminal is pulled up toward the supply terminal. Also, because the transistor 504 is injecting current, the transistor 506 will conduct more current, which allows the voltage at the Vop terminal to be pulled toward ground.

FIG. 6 is a circuit implementation of the CML frequency doubler 302, the clock buffer 304, 500 and the feedback amplifier 306 of at least one of FIGS. 3-5. The clock buffer 304, 500 includes the transistors 502, 504, 506, 508, the resistors 510, 512, 514, 516, 522, 524, and the capacitor 520. However, as described above, the capacitor 520 and the resistors 522, 524 are optional. The CML frequency doubler 302 includes example transistors 600, 602, 604, 606, 608, 610, 616 example current source circuitry 611, an example resistor 612, 614. The feedback amplifier 306 includes example current source circuitry 618, an example resistor 620, and an example operational amplifier 622. The structure and function of the clock buffer 304, 500 of FIG. 6 is the same, or substantially similar to the clock buffer 304, 500 of FIG. 5A. Accordingly, the clock buffer 304, 500 of FIG. 6 will not further be described. Further description of the clock buffer 304, 500 of FIG. 6 can be ascertained from the description of FIG. 5A.

The transistors 600, 602, 604, 606 of FIG. 6 are NPN bipolar junction transistors (BJTs). However, the transistors 600, 602, 604, 606 could be any type of transistor. The transistors 600, 602, 604, 606 each include a control terminal, a first current terminal, and a second current terminal. The control terminal of the transistor 600 is coupled to the clock and data recovery circuitry 206 via the d0 terminal. The first current terminal of the transistor 600 is coupled to the first current terminal of the transistor 602, the second terminal of the resistor 612, and the control terminal of the transistor 504 via the Vin terminal of the clock buffer 304, 500. The second current terminal of the transistor 600 is coupled to the second current terminal of the transistor 606 and the first current terminal of the transistor 608. The control terminal of the transistor 602 is coupled to the clock and data recovery circuitry 206 via the d1 terminal. The first current terminal of the transistor 602 is coupled to the first current terminal of the transistor 600, the second terminal of the resistor 612 and the control terminal of the transistor 504 via the Vin terminal of the clock buffer 304, 500. The second current terminal of the transistor 602 is coupled to the second current terminal of the transistor 604 and the first current terminal of the transistor 610. The control terminal of the transistor 604 is coupled to the clock and data recovery circuitry 206 via the d1z terminal. The first current terminal of the transistor 604 is coupled to the first current terminal of the transistor 606, the second terminal of the resistor 614, and the control terminal of the transistor 502 via the Vip terminal of the clock buffer 304, 500. The second current terminal of the transistor 604 is coupled to the second current terminal of the transistor 602 and the first current terminal of the transistor 610. The control terminal of the transistor 606 is coupled to the clock and data recovery circuitry 206 via the d0z terminal. The first current terminal of the transistor 606 is coupled to the first current terminal of the transistor 604, the second terminal of the resistor 614 and the control terminal of the transistor 502 via the Vip terminal of the clock buffer 304, 500. The second current terminal of the transistor 606 is coupled to the second current terminal of the transistor 600 and the first current terminal of the transistor 608. The clock and data recovery circuitry 206 outputs four signals to the control terminals of the transistors 600, 602, 604, 606 via the d1, d0, d1z and d0z terminals. The clock and data recovery circuitry 206 outputs a first clock signal at the d0 terminal, a second clock signal with a 180-degree phase shift from the first clock signal at the d1 terminal, a third clock signal with a 180-degree phase shift from the first clock signal at the d1z terminal, and a fourth clock signal with a 0-degree phase shift from the first clock signal at the d0z terminal.

The transistors 608, 610 of FIG. 6 are NPN bipolar junction transistors (BJTs). However, the transistors 608, 610 could be any type of transistor. The transistors 608, 610 each include a control terminal, a first current terminal, and a second current terminal. The control terminal of the transistor 608 is coupled to the clock and data recovery circuitry 206 via the s terminal. The first current terminal of the transistor 608 is coupled to the second current terminal of the transistor 600 and the second current terminal of the transistor 606. The second current terminal of the transistor 608 is coupled to the second current terminal of the transistor 610 and the first terminal of the current source circuitry 611. The control terminal of the transistor 608 is coupled to the clock and data recovery circuitry 206 via the sz terminal. The first current terminal of the transistor 610 is coupled to the second current terminal of the transistor 602 and the second current terminal of the transistor 604. The second current terminal of the transistor 610 is coupled to the second terminal of the transistor 608 and the first terminal of the current source circuitry 611. The clock and data recovery circuitry 206 outputs two clock signals to the control terminals of the transistors 608, 610. The first clock signal at the s terminal is 90 degrees out of phase with the first clock signal at the d1 terminal. The second clock signal at the sz terminal is 270 degrees out of phase with the first clock signal at the d1 terminal.

The current source circuitry 611 of FIG. 6 includes a first terminal and a second terminal. The first terminal of the current source circuitry 611 is coupled to the second current terminal of the transistor 608 and the second current terminal of the transistor 610. The second terminal of the current source circuitry 611 is coupled to a common terminal (e.g., the ground terminal). The current source circuitry 611 draws current toward the common terminal. In some examples, the current source circuitry 611 is implemented with a resistor.

The resistors 612, 614 of FIG. 6 each include a first terminal and a second terminal. The first terminal of the resistor 612 is coupled to the first terminal of the resistor 614 and the second current terminal of the transistor 616. The second terminal of the resistor 612 is coupled to the first current terminals of the transistors 600, 602 and the control terminal of the transistor 504 of the clock buffer 304, 500. The first terminal of the resistor 614 is coupled to the first terminal of the resistor 612 and the second current terminal of the transistor 616. The second terminal of the resistor 614 is coupled to the first current terminals of the 604, 606 and the control terminal of the transistor 502 of the clock buffer 304, 500.

The transistor 616 of FIG. 6 is a p-channel metal oxide semiconductor (PMOS) field effect transistor (FET, MOSFET). However, the transistor 616 could be a different type of transistor. The transistor 616 includes a control terminal (e.g., a gate terminal), a first current terminal (e.g., a source terminal), and a second current terminal (e.g., a drain terminal). The control terminal of the transistor 616 is coupled to the output of the operational amplifier 622 of the feedback amplifier 306. The first current terminal of the transistor 616 is coupled to a supply terminal. The second current terminal of the transistor 616 is coupled to the first terminals of the resistors 612, 614. The transistor 616 controls how much of the supply voltage to apply to the resistors 612, 614 based on the output voltage of the operational amplifier 622. As further described below, the output voltage of the operational amplifier 622 is a function of the difference of the common mode voltage of the clock buffer 304, 500 to the desired common mode voltage. Accordingly, if there is no deviation from the desired common mode voltage, the operational amplifier 622 will output a particular voltage to control the output clock signals to maintain the desired common mode voltage. However, if the voltage differential increases or decreases, the amount of voltage applied to the resistor 612, 614 decreases or increase to adjust the output clock signals by turning on the transistor 616 more or less to adjust the common mode voltage closer to the desired common mode voltage.

The circuitry of the CML frequency doubler 302 of FIG. 6 is structured to operate as an exclusive or (XOR) circuit that increases the frequency of the clock signal from the clock and data recovery circuitry 206 to a full-rate clock. For example, the clock and data recovery circuitry 206 generates differential 14 GHz clock signals and the output clock signals at the Vip and Vin terminals are differential 28 GHz clock signals.

The current source circuitry 618 of FIG. 6 includes a first terminal and a second terminal. The first terminal of the current source circuitry 618 is coupled to a supply terminal. The second terminal of the current source circuitry 618 is coupled to the second input terminal of the operational amplifier 622 and the first terminal of the resistor 620. The current source circuitry 618 draws a current from the supply terminal to the resistor 620 to generate a reference voltage. The current source circuitry 618 can be implemented by a resistor. The current source circuitry 618 and the resistor 620 are structured to generate a reference voltage at the second input terminal of the operational amplifier 622 that corresponds to the desired common mode voltage. Although FIG. 6 illustrates one way to generate a reference voltage, FIG. 6 could include any alternative way to generate a reference voltage.

The resistor 620 of FIG. 6 includes a first terminal and a second terminal. The first terminal of the resistor 620 is coupled to the second terminal of the current source circuitry 618 and the second input terminal of the operational amplifier 622. The second terminal of the resistor 620 is coupled to the common terminal (e.g., ground). In some examples, an example capacitor 621 can be added in parallel with the resistor 620 to filter out noise at the Vref node. The optional capacitor 621 includes a first terminal and a second terminal. The first terminal of the capacitor 621 is coupled to the second terminal of the current source circuitry 618, the second input terminal of the amplifier 622 and the first terminal of the resistor 620. The second terminal of the capacitor 621 is coupled to the common terminal.

The operational amplifier 622 of FIG. 6 includes a first input terminal (e.g., a non-inverting terminal) and a second input terminal (e.g., an inverting terminal), and an output terminal. The first input terminal of the operational amplifier 622 is coupled to the Vcm terminal 518 of the clock buffer 304. The second input terminal of the operational amplifier 622 is coupled to the second terminal of the current source circuitry 618 and the first terminal of the resistor 620. The output terminal of the operational amplifier 622 is coupled to the control terminal of the transistor 616 of the CML frequency doubler circuitry 302. The operational amplifier 622 compares the common mode voltage at the Vcm node 518 to the reference voltage at the Vref node of the feedback amplifier 306. If the common mode voltage is the same as the reference voltage (e.g., the desired common mode voltage), the operational amplifier 622 outputs a voltage. Accordingly, the transistor 616 will output a particular voltage lower than the Vdd voltage to the resistors 612, 614 and the output clock signals from the CML frequency doubler 302 will not be adjusted. However, if the voltage difference between the common mode voltage to the reference voltage increases, the output voltage of the operational amplifier 622 will increase, thereby causing the voltage applied to the resistors 612, 614 to decrease. As described above, decreasing the voltage applied to the resistors 612, 614 adjusts the common mode voltage of the output clock signals from the CML frequency doubler circuitry 302 to mitigate the deviation of the common mode voltage from the desired common mode voltage.

FIG. 7 is a circuit diagram of the clock buffer 304, 500 and the feedback amplifier 306 of the clock distribution circuitry 400 of FIG. 4. The clock buffer 304, 500 includes the transistors 502, 504, 506, 508, the resistors 510, 512, 514, 516, 522, 524, and the capacitor 520. However, as described above, the capacitor 520 and the resistors 522, 524 are optional. The feedback amplifier 306 includes the example current source circuitry 618, the example resistor 620, and the example operational amplifier 622 of FIG. 6. FIG. 7 further includes the resistors 402, 404, and the capacitors 406, 408 of FIG. 4. The structure and function of the clock buffer 304, 500 and the feedback amplifier 308 of FIG. 7 are the same, or substantially similar to the clock buffer 304, 500 and the feedback amplifier 308 of FIG. 6, but for how the components are connected. Accordingly, the clock buffer 304, 500 and the feedback amplifier 308 of FIG. 7 will not further be described except for the differences to FIG. 6. Further description of the clock buffer 304, 500 and the feedback amplifier 308 of FIG. 7 can be ascertained from the description of FIG. 6. In the example of FIG. 7, the previous stage could be the CML frequency doubler circuitry 401 of FIG. 4. In some examples, the CML frequency doubler circuitry 401 could be implemented by the CML frequency doubler 302 of FIG. 6. However, because the output of the feedback amplifier 306 is not coupled to the transistor 616 of FIG. 6, the transistor 616 can be replaced with a short circuit or the control terminal of the transistor 616 can be coupled to ground to have the transistor 616 operate as a short circuit.

In the example of FIG. 7, the output terminal of the operational amplifier 622 is coupled to the first terminal of the resistors 402, 404. As described above, the output voltage of the operational amplifier 622 corresponds to the deviation of the common mode voltage of the clock buffer 304, 500 from the desired common mode voltage. Accordingly, the output voltage of the operational amplifier 622 is pumped into the input terminals (Vip and Vin) of the clock buffer 304, 500. Accordingly, the differential clock signals that are input into the clock buffer 304, 500 are adjusted to mitigate the deviation of the common mode voltage of the clock buffer from the desired common mode voltage, as further described above in conjunction with FIG. 4.

One or more example manners of implementing the transmitter circuitry 106 of FIG. 1 or the clock distribution circuitry 207 of FIG. 2 is illustrated in FIGS. 2-7. However, one or more of the elements, processes or devices illustrated in FIGS. 2-7 may be combined, divided, re-arranged, omitted, eliminated or implemented in any other way.

As used herein, the phrase “in communication,” including variations thereof, encompasses direct communication or indirect communication through one or more intermediary components, and does not require direct physical (e.g., wired) communication or constant communication, but rather also includes selective communication at one or more of periodic intervals, scheduled intervals, aperiodic intervals, or one-time events.

Although certain example methods, apparatus and articles of manufacture have been described herein, the scope of coverage of this patent is not limited thereto. On the contrary, this patent covers all methods, apparatus and articles of manufacture fairly falling within the scope of the claims of this patent.

Descriptors “first,” “second,” “third,” etc. are used herein when identifying multiple elements or components which may be referred to separately. Unless otherwise specified or known based on their context of use, such descriptors do not impute any meaning of priority, physical order, or arrangement in a list, or ordering in time but are merely used as labels for referring to multiple elements or components separately for ease of understanding the described examples. In some examples, the descriptor “first” may be used to refer to an element in the detailed description, while the same element may be referred to in a claim with a different descriptor such as “second” or “third.” In such instances, such descriptors are used merely for ease of referencing multiple elements or components.

In the description and in the claims, the terms “including” and “having,” and variants thereof are to be inclusive in a manner similar to the term “comprising” unless otherwise noted. Unless otherwise stated, “about,” “approximately,” or “substantially” preceding a value means +/−10 percent of the stated value. In another example, “about,” “approximately,” or “substantially” preceding a value means +/−5 percent of the stated value. IN another example, “about,” “approximately,” or “substantially” preceding a value means +/−1 percent of the stated value.

The terms “couple,” “coupled,” “couples,” and variants thereof, as used herein, may cover connections, communications, or signal paths that enable a functional relationship consistent with this description. For example, if device A generates a signal to control device B to perform an action, if a first example device A is coupled to device B, or if a second example device A is coupled to device B through intervening component C if intervening component C does not substantially alter the functional relationship between device A and device B, such that device B is controlled by device A via the control signal generated by device A. Moreover, the terms “couple,” “coupled”, “couples”, or variants thereof, includes an indirect or direct electrical or mechanical connection.

A device that is “configured to” perform a task or function may be configured (e.g., at least one of programmed or hardwired) at a time of manufacturing by a manufacturer to perform the function or may be configurable (or re-configurable) by a user after manufacturing to perform the function or other additional or alternative functions. The configuring may be through at least one of firmware or software programming of the device, through a construction or layout of hardware components and interconnections of the device, or a combination thereof.

Although not all separately labeled in the FIGS. 1-7, components or elements of systems and circuits illustrated therein have one or more conductors or terminus that allow signals into or out of the components or elements. The conductors or terminus (or parts thereof) may be referred to herein as pins, pads, terminals (including input terminals, output terminals, reference terminals, and ground terminals, for instance), inputs, outputs, nodes, and interconnects.

As used herein, a “terminal” of a component, device, system, circuit, integrated circuit, or other electronic or semiconductor component, generally refers to a conductor such as a wire, trace, pin, pad, or other connector or interconnect that enables the component, device, system, etc., to electrically or mechanically connect to another component, device, system, etc. A terminal may be used, for instance, to receive or provide analog or digital electrical signals (or simply signals) or to electrically connect to a common or ground reference. Accordingly, an input terminal or input is used to receive a signal from another component, device, system, etc. An output terminal or output is used to provide a signal to another component, device, system, etc. Other terminals may be used to connect to a common, ground, or voltage reference, e.g., a reference terminal or ground terminal. A terminal of an IC or a PCB may also be referred to as a pin (a longitudinal conductor) or a pad (a planar conductor). A node refers to a point of connection or interconnection of two or more terminals. An example number of terminals and nodes may be shown. However, depending on a particular circuitry or system topology, there may be more or fewer terminals and nodes. However, in some instances, “terminal,” “node,” “interconnect,” “pad,” and “pin” may be used interchangeably.

The term “of” when used, for example, in a form such as A, B, or C refers to any combination or subset of A, B, C such as (1) A alone, (2) B alone, (3) C alone, (4) A with B, (5) A with C, (6) B with C, or (7) A with B and with C.

Example methods, apparatus, systems, and articles of manufacture corresponding to facilitate phase detection for data clock synchronization are described herein. Further examples and combinations thereof include the following: Example 1 includes a circuit comprising a first transistor having a control terminal, a first current terminal, and a second current terminal, a second transistor having a control terminal, a first current terminal, and a second current terminal, a third transistor having a control terminal, a first current terminal, and a second current terminal, the control terminal of the third transistor coupled to the second current terminal of the second transistor, the first current terminal of the third transistor coupled to the second current terminal of the first transistor, a fourth transistor having a control terminal, a first current terminal, and a second current terminal, the control terminal of the fourth transistor coupled to the second current terminal of the first transistor and the first current terminal of the third transistor, the first current terminal of the fourth transistor coupled to the second current terminal of the second transistor and the control terminal of the third transistor, a first resistor having a first terminal and a second terminal, the first terminal of the first resistor coupled to the second current terminal of the third transistor, and a second resistor having a first terminal and a second terminal, the first terminal of the second resistor coupled to the second current terminal of the fourth transistor.

Example 2 includes the circuit of example 1, wherein the second terminal of the first resistor coupled to a common terminal, the second terminal of the second resistor coupled to the common terminal, the first current terminal of the first transistor coupled to a supply terminal, and the first current terminal of the second transistor coupled to the supply terminal.

Example 3 includes the circuit of example 1, further including a third resistor having a first terminal and a second terminal, the first terminal of the third resistor coupled to the second current terminal of the first transistor and the control terminal of the fourth transistor, the second terminal of the third resistor coupled to the first current terminal of the third transistor, the first current terminal of the third transistor coupled to the second current terminal of the first transistor and the control terminal of the fourth transistor via the third resistor, and a fourth resistor having a first terminal and a second terminal, the first terminal of the fourth resistor coupled to the second current terminal of the second transistor and the control terminal of the third transistor, the second terminal of the fourth resistor coupled to the first current terminal of the fourth transistor, the first current terminal of the fourth transistor coupled to the second current terminal of the second transistor and the control terminal of the third transistor via the fourth resistor.

Example 4 includes the circuit of example 1, further including a capacitor having a first terminal and a second terminal, the first terminal of the capacitor coupled to the second current terminal of the third transistor and the first terminal of the first resistor, the second terminal of the capacitor coupled to the second current terminal of the fourth transistor and the first current terminal of the second resistor.

Example 5 includes the circuit of example 1, further including a third resistor having a first terminal and a second terminal, the first terminal of the third resistor coupled to the second current terminal of the third transistor and the first terminal of the first resistor, and a fourth resistor having a first terminal and a second terminal, the first terminal of the fourth resistor coupled to the second terminal of the third resistor, the second terminal of the fourth resistor coupled to the second current terminal of the fourth transistor and the first terminal of the second resistor.

Example 6 includes the circuit of example 5, wherein the second terminal of the third resistor and the first terminal of the fourth resistor are structured to be coupled to a feedback amplifier.

Example 7 includes the circuit of example 1, further including: a third resistor having a first terminal and a second terminal, the first terminal of the third resistor coupled to the first current terminal of the third transistor and the second current terminal of the first transistor; and a fourth resistor having a first terminal and a second terminal, the first terminal of the fourth resistor coupled to the second terminal of the third resistor, the second terminal of the fourth resistor coupled to the first current terminal of the fourth transistor and the second current terminal of the second transistor.

Example 8 includes the circuit of example 1, wherein the control terminal of the first transistor is a first input terminal of the circuit, the control terminal of the second transistor is a second input terminal of the circuit, the first current terminal of the third transistor is a first output terminal of the buffer, and the first current terminal of the fourth transistor is a second output terminal of the buffer.

Example 9 includes an apparatus comprising clock buffer circuitry including a first resistor having a first terminal and a second terminal, a second resistor having a first terminal and a second terminal, the second terminal of the second resistor coupled to the first terminal of the first resistor, and a common mode voltage node, the second terminal of the second resistor coupled to the first terminal of the first resistor via the common mode voltage node, and a feedback amplifier including a third resistor having a first terminal and a second terminal, a current source circuitry having a first terminal and a second terminal, the second terminal of the current source circuitry coupled to the first terminal of the third resistor, and an amplifier having a first input terminal, a second input terminal, and an output terminal, the first input terminal of the amplifier coupled to the second terminal of the first resistor and the first terminal of the second resistor, the second input terminal of the amplifier coupled to the second terminal of the current source circuitry and the first terminal of the third resistor.

Example 10 includes the apparatus of example 9, wherein the clock buffer circuitry includes a first transistor having a control terminal, a first current terminal, and a second current terminal, a second transistor having a control terminal, a first current terminal, and a second current terminal, a third transistor having a control terminal, a first current terminal, and a second current terminal, the control terminal of the third transistor coupled to the second current terminal of the second transistor, the first current terminal of the third transistor coupled to the second current terminal of the first transistor, the second current terminal of the third resistor coupled to the first terminal of the first resistor, and a fourth transistor having a control terminal, a first current terminal, and a second current terminal, the control terminal of the fourth transistor coupled to the second current terminal of the first transistor and the first current terminal of the third transistor, the first current terminal of the fourth transistor coupled to the second current terminal of the second transistor and the control terminal of the third transistor, the second current terminal of the fourth transistor coupled to second terminal of the second resistor.

Example 11 includes the apparatus of example 10, wherein the first current terminal of the first transistor is coupled to a supply terminal, the first current terminal of the second transistor is coupled to the supply terminal, the first terminal of the current source circuitry is coupled to the supply terminal, and the second terminal of the third transistor is coupled to a common terminal.

Example 12 includes the apparatus of example 10, further including a fourth resistor having a first terminal and a second terminal, the first terminal of the fourth resistor coupled to the output terminal of the amplifier, the second terminal of the fourth resistor coupled to the control terminal of the first transistor, and a fifth resistor having a first terminal and a second terminal, the first terminal of the fifth resistor coupled to the output terminal of the amplifier and the first terminal of the fourth resistor, the second terminal of the fifth resistor coupled to the control terminal of the second transistor.

Example 13 includes the apparatus of example 10, further including frequency adjuster circuitry including a fifth transistor having a control terminal, a first current terminal, and a second current terminal, the control terminal of the fifth transistor coupled to the output terminal of the amplifier, the first current terminal of the fifth transistor coupled to a supply terminal, a fourth resistor having a first terminal and a second terminal, the first terminal of the fourth resistor coupled to the second current terminal of the fifth transistor, the second terminal of the fourth resistor coupled to the control terminal of the first transistor, and a fifth resistor having a first terminal and a second terminal, the first terminal of the fifth resistor coupled to the second current terminal of the fifth transistor, the second terminal of the fifth resistor coupled to the control terminal of the second transistor.

Example 14 includes the apparatus of example 10, wherein the first current terminal of the third transistor is a first output terminal of the clock buffer circuitry, and the first current terminal of the fourth transistor is a second output terminal of the clock buffer circuitry.

Example 15 includes an apparatus comprising an oscillator having an output, frequency adjuster circuitry having an input, a first output, and a second output, the input of the frequency adjuster circuitry coupled to the output of the oscillator, a clock buffer circuitry including a first resistor having a first terminal and a second terminal, and a second resistor having a first terminal and a second terminal, the second terminal of the second resistor coupled to the first terminal of the first resistor, and a feedback amplifier having a first input, a second input, and an output, the first input of the feedback amplifier coupled to a second terminal of the first resistor and a first terminal of the second resistor.

Example 16 includes the apparatus of example 15, wherein the clock buffer circuitry includes a first transistor having a control terminal, a first current terminal, and a second current terminal, the control terminal of the first transistor coupled to the first output of the frequency adjuster circuitry, a second transistor having a control terminal, a first current terminal, and a second current terminal, the control terminal of the second transistor coupled to the second output of the frequency adjuster circuitry, a third transistor having a control terminal, a first current terminal, and a second current terminal, the control terminal of the third transistor coupled to the second current terminal of the second transistor, the first current terminal of the third transistor coupled to the second current terminal of the first transistor, and a fourth transistor having a control terminal, a first current terminal, and a second current terminal, the control terminal of the fourth transistor coupled to the second current terminal of the first transistor and the first current terminal of the third transistor, the first current terminal of the fourth transistor coupled to the second current terminal of the second transistor and the control terminal of the third transistor, the second current terminal of the fourth transistor coupled to the second current terminal of the third transistor via the first and second resistors.

Example 17 includes the apparatus of example 16, further including a fourth resistor having a first terminal and a second terminal, the first terminal of the fourth resistor coupled to the output of the feedback amplifier, the second terminal of the fourth resistor coupled to the control terminal of the first transistor, and a fifth resistor having a first terminal and a second terminal, the first terminal of the fifth resistor coupled to the output of the feedback amplifier and the first terminal of the fourth resistor, the second terminal of the fifth resistor coupled to the control terminal of the second transistor.

Example 18 includes the apparatus of example 17, further including a first capacitor and a second capacitor, wherein the first output of the frequency adjuster circuitry is coupled to the control terminal of the first transistor via the first capacitor and the second output of the frequency adjuster circuitry is coupled to the control terminal of the second transistor via the second capacitor.

Example 19 includes the apparatus of example 16, wherein the input of the frequency adjuster circuitry is a first input and the frequency adjuster circuitry includes a second input, the output of the feedback amplifier coupled to the second input of the frequency adjuster circuitry.

Example 20 includes the apparatus of example 16, wherein the feedback amplifier outputs a voltage based on a comparison of a common mode voltage of the clock buffer circuitry to a reference voltage.

Example 21 includes the apparatus of example 20, wherein the voltage adjusts the common mode voltage of the clock buffer circuitry.

Example 22 includes the apparatus of example 21, wherein the first current terminal of the first transistor coupled to a supply terminal, and the first current terminal of the second transistor coupled to the supply terminal, further including a third resistor having a first terminal and a second terminal, the first terminal of the third resistor coupled to the second current terminal of the third transistor, the second terminal of the third resistor coupled to a common terminal, and a fourth resistor having a first terminal and a second terminal, the first terminal of the fourth resistor coupled to the second current terminal of the fourth transistor, the second terminal of the fourth resistor coupled to the common terminal.

Modifications are possible in the described examples, and other examples are possible, within the scope of the claims.

1. A circuit comprising:
a first transistor having a control terminal, a first current terminal, and a second current terminal;
a second transistor having a control terminal, a first current terminal, and a second current terminal;
a third transistor having a control terminal, a first current terminal, and a second current terminal, the control terminal of the third transistor coupled to the second current terminal of the second transistor, the first current terminal of the third transistor coupled to the second current terminal of the first transistor;
a fourth transistor having a control terminal, a first current terminal, and a second current terminal, the control terminal of the fourth transistor coupled to the second current terminal of the first transistor and the first current terminal of the third transistor, the first current terminal of the fourth transistor coupled to the second current terminal of the second transistor and the control terminal of the third transistor;
a first resistor having a first terminal and a second terminal, the first terminal of the first resistor coupled to the second current terminal of the third transistor; and
a second resistor having a first terminal and a second terminal, the first terminal of the second resistor coupled to the second current terminal of the fourth transistor.

2. The circuit of claim 1, wherein the second terminal of the first resistor coupled to a common terminal, the second terminal of the second resistor coupled to the common terminal, the first current terminal of the first transistor coupled to a supply terminal, and the first current terminal of the second transistor coupled to the supply terminal.

3. The circuit of claim 1, further including:
a third resistor having a first terminal and a second terminal, the first terminal of the third resistor coupled to the second current terminal of the first transistor and the control terminal of the fourth transistor, the second terminal of the third resistor coupled to the first current terminal of the third transistor, the first current terminal of the third transistor coupled to the second current terminal of the first transistor and the control terminal of the fourth transistor via the third resistor; and
a fourth resistor having a first terminal and a second terminal, the first terminal of the fourth resistor coupled to the second current terminal of the second transistor and the control terminal of the third transistor, the second terminal of the fourth resistor coupled to the first current terminal of the fourth transistor, the first current terminal of the fourth transistor coupled to the second current terminal of the second transistor and the control terminal of the third transistor via the fourth resistor.

4. The circuit of claim 1, further including a capacitor having a first terminal and a second terminal, the first terminal of the capacitor coupled to the second current terminal of the third transistor and the first terminal of the first resistor, the second terminal of the capacitor coupled to the second current terminal of the fourth transistor and the first current terminal of the second resistor.

5. The circuit of claim 1, further including:
a third resistor having a first terminal and a second terminal, the first terminal of the third resistor coupled to the second current terminal of the third transistor and the first terminal of the first resistor; and
a fourth resistor having a first terminal and a second terminal, the first terminal of the fourth resistor coupled to the second terminal of the third resistor, the second terminal of the fourth resistor coupled to the second current terminal of the fourth transistor and the first terminal of the second resistor.

6. The circuit of claim 5, wherein the second terminal of the third resistor and the first terminal of the fourth resistor are structured to be coupled to a feedback amplifier.

7. The circuit of claim 1, further including:
a third resistor having a first terminal and a second terminal, the first terminal of the third resistor coupled to the first current terminal of the third transistor and the second current terminal of the first transistor; and
a fourth resistor having a first terminal and a second terminal, the first terminal of the fourth resistor coupled to the second terminal of the third resistor, the second terminal of the fourth resistor coupled to the first current terminal of the fourth transistor and the second current terminal of the second transistor.

8. The circuit of claim 1, wherein the control terminal of the first transistor is a first input terminal of the circuit, the control terminal of the second transistor is a second input terminal of the circuit, the first current terminal of the third transistor is a first output terminal of the buffer, and the first current terminal of the fourth transistor is a second output terminal of the buffer.

9. An apparatus comprising:
clock buffer circuitry including:
a first resistor having a first terminal and a second terminal;
a second resistor having a first terminal and a second terminal, the second terminal of the second resistor coupled to the first terminal of the first resistor; and
a common mode voltage node, the second terminal of the second resistor coupled to the first terminal of the first resistor via the common mode voltage node; and
a feedback amplifier including:
a third resistor having a first terminal and a second terminal;
a current source circuitry having a first terminal and a second terminal, the second terminal of the current source circuitry coupled to the first terminal of the third resistor; and
an amplifier having a first input terminal, a second input terminal, and an output terminal, the first input terminal of the amplifier coupled to the second terminal of the first resistor and the first terminal of the second resistor, the second input terminal of the amplifier coupled to the second terminal of the current source circuitry and the first terminal of the third resistor.

10. The apparatus of claim 9, wherein the clock buffer circuitry includes:
a first transistor having a control terminal, a first current terminal, and a second current terminal;
a second transistor having a control terminal, a first current terminal, and a second current terminal;
a third transistor having a control terminal, a first current terminal, and a second current terminal, the control terminal of the third transistor coupled to the second current terminal of the second transistor, the first current terminal of the third transistor coupled to the second current terminal of the first transistor, the second current terminal of the third resistor coupled to the first terminal of the first resistor; and
a fourth transistor having a control terminal, a first current terminal, and a second current terminal, the control terminal of the fourth transistor coupled to the second current terminal of the first transistor and the first current terminal of the third transistor, the first current terminal of the fourth transistor coupled to the second current terminal of the second transistor and the control terminal of the third transistor, the second current terminal of the fourth transistor coupled to second terminal of the second resistor.

11. The apparatus of claim 10, wherein the first current terminal of the first transistor is coupled to a supply terminal, the first current terminal of the second transistor is coupled to the supply terminal, the first terminal of the current source circuitry is coupled to the supply terminal, and the second terminal of the third transistor is coupled to a common terminal.

12. The apparatus of claim 10, further including:
a fourth resistor having a first terminal and a second terminal, the first terminal of the fourth resistor coupled to the output terminal of the amplifier, the second terminal of the fourth resistor coupled to the control terminal of the first transistor; and
a fifth resistor having a first terminal and a second terminal, the first terminal of the fifth resistor coupled to the output terminal of the amplifier and the first terminal of the fourth resistor, the second terminal of the fifth resistor coupled to the control terminal of the second transistor.

13. The apparatus of claim 10, further including frequency adjuster circuitry including:
a fifth transistor having a control terminal, a first current terminal, and a second current terminal, the control terminal of the fifth transistor coupled to the output terminal of the amplifier, the first current terminal of the fifth transistor coupled to a supply terminal;
a fourth resistor having a first terminal and a second terminal, the first terminal of the fourth resistor coupled to the second current terminal of the fifth transistor, the second terminal of the fourth resistor coupled to the control terminal of the first transistor; and
a fifth resistor having a first terminal and a second terminal, the first terminal of the fifth resistor coupled to the second current terminal of the fifth transistor, the second terminal of the fifth resistor coupled to the control terminal of the second transistor.

14. The apparatus of claim 10, wherein the first current terminal of the third transistor is a first output terminal of the clock buffer circuitry, and the first current terminal of the fourth transistor is a second output terminal of the clock buffer circuitry.

15. An apparatus comprising:
an oscillator having an output;
frequency adjuster circuitry having an input, a first output, and a second output, the input of the frequency adjuster circuitry coupled to the output of the oscillator;
a clock buffer circuitry including:
a first resistor having a first terminal and a second terminal; and
a second resistor having a first terminal and a second terminal, the second terminal of the second resistor coupled to the first terminal of the first resistor; and
a feedback amplifier having a first input, a second input, and an output, the first input of the feedback amplifier coupled to a second terminal of the first resistor and a first terminal of the second resistor.

16. The apparatus of claim 15, wherein the clock buffer circuitry includes:
a first transistor having a control terminal, a first current terminal, and a second current terminal, the control terminal of the first transistor coupled to the first output of the frequency adjuster circuitry;
a second transistor having a control terminal, a first current terminal, and a second current terminal, the control terminal of the second transistor coupled to the second output of the frequency adjuster circuitry;
a third transistor having a control terminal, a first current terminal, and a second current terminal, the control terminal of the third transistor coupled to the second current terminal of the second transistor, the first current terminal of the third transistor coupled to the second current terminal of the first transistor; and
a fourth transistor having a control terminal, a first current terminal, and a second current terminal, the control terminal of the fourth transistor coupled to the second current terminal of the first transistor and the first current terminal of the third transistor, the first current terminal of the fourth transistor coupled to the second current terminal of the second transistor and the control terminal of the third transistor, the second current terminal of the fourth transistor coupled to the second current terminal of the third transistor via the first and second resistors.

17. The apparatus of claim 16, further including:
a fourth resistor having a first terminal and a second terminal, the first terminal of the fourth resistor coupled to the output of the feedback amplifier, the second terminal of the fourth resistor coupled to the control terminal of the first transistor; and
a fifth resistor having a first terminal and a second terminal, the first terminal of the fifth resistor coupled to the output of the feedback amplifier and the first terminal of the fourth resistor, the second terminal of the fifth resistor coupled to the control terminal of the second transistor.

18. The apparatus of claim 17, further including a first capacitor and a second capacitor, wherein the first output of the frequency adjuster circuitry is coupled to the control terminal of the first transistor via the first capacitor and the second output of the frequency adjuster circuitry is coupled to the control terminal of the second transistor via the second capacitor.

19. The apparatus of claim 16, wherein the input of the frequency adjuster circuitry is a first input and the frequency adjuster circuitry includes a second input, the output of the feedback amplifier coupled to the second input of the frequency adjuster circuitry.

20. The apparatus of claim 16, wherein the feedback amplifier outputs a voltage based on a comparison of a common mode voltage of the clock buffer circuitry to a reference voltage.

21. (canceled)

22. (canceled)
